(19) United States
(12) Patent Application Publication
(10) Pub. No.: US 2006/0170034 A1
(43) Pub. Date: Aug. 3, 2006

(54) Non-volatile memory device and method of manufacturing the same

(75) Inventors: Sung-Woo Park, Gunpo-si (KR); Sung-Taeg Kang, Suwon-si (KR); Seung-Beom Yoon, Suwon-si (KR); Yong-Tae Kim, Yongin-si (KR); Ji-Hoon Park, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/339,741

(22) Filed: Jan. 25, 2006

(30) Foreign Application Priority Data
Feb. 3, 2005 (KR) 2005-0010237

(51) Int. Cl. H01L 29/792

(52) U.S. Cl. 257/324

(57) ABSTRACT

Provided are a non-volatile memory device having an improved electric characteristic and a method of manufacturing the non-volatile memory device, where the non-volatile memory device includes a substrate having a sloped portion formed therein, a first gate electrode pattern having a stacked structure in which an electric charge tunneling layer pattern, an electric charge trapping layer pattern, an electric charge shielding layer pattern, and a storage gate electrode pattern are conformably stacked on the sloped portion, a gate insulating layer pattern extending from a side of the first gate electrode pattern to the substrate, a second gate electrode pattern formed on the gate insulating layer pattern, a first junction region arranged at a side wall of the first gate electrode pattern, which does not face the second gate electrode pattern, and formed in the substrate, and a second junction region arranged at a side wall of the second gate electrode pattern, which does not face the first gate electrode pattern, and formed in the substrate.

### CROSS-REFERENCE TO RELATED APPLICATION

This application claims foreign priority under 35 U.S.C. § 119 to Korean Patent Application No. 10-2005-0010237, filed on Feb. 3, 2005, in the Korean Intellectual Property Office, the disclosure of which is incorporated herein by reference in its entirety.

### BACKGROUND OF THE INVENTION

1. Field of the Invention

The present disclosure relates to a memory devices and methods of manufacturing the same, and more particularly, to non-volatile memory devices and methods of manufacturing non-volatile memory devices.

2. Description of the Related Art

A non-volatile memory device can maintain stored information even when power is no longer supplied to it. In line with the tendency of making electronic devices smaller and portable, there is an increased demand for non-volatile memory devices. The most popular and widely used non-volatile memory device is a FLASH memory device including a floating gate. Research is being actively conducted on a silicon-oxide-nitride-oxide-silicon (SONOS) type non-volatile memory device that uses a thin tunneling insulating film.

Generally, the SONOS type non-volatile memory device includes an electric charge tunneling layer formed of an oxide, an electric charge trapping layer formed of a nitride, an electric charge shielding layer formed of an oxide, and a gate electrode formed of polysilicon, which are sequentially stacked on a semiconductor substrate. The electric charge trapping layer is used as an electric charge trapping medium.

To perform a program operation in which an electric charge is trapped in the electric charge trapping layer, a vertical electric field is formed by applying a high voltage to the gate electrode in order to move an electric charge from a channel region of the substrate into the electric charge trapping layer. Unfortunately, according to this approach, since a high threshold voltage should be applied to the gate electrode, power dissipation is high.

Thus, there is a need for a SONOS type non-volatile memory device that can reduce power dissipation during a program operation.

### SUMMARY OF THE INVENTION

The present disclosure provides a non-volatile memory device having an improved electric characteristic. The present disclosure also provides a method of manufacturing a non-volatile memory device having an improved electric characteristic.

According to an aspect of the present disclosure, there is provided a non-volatile memory device including a substrate having a trench formed therein, a first gate electrode pattern having a stacked structure in which an electric charge tunneling layer pattern, an electric charge trapping layer pattern, an electric charge shielding layer pattern, and a storage gate electrode pattern are conformably stacked on the trench and a region of the substrate adjacent to the trench, a gate insulating layer pattern extending from a side of the first gate electrode pattern to the substrate, a second gate electrode pattern formed on the gate insulating layer pattern, a first junction region arranged at a side wall of the first gate electrode pattern, which does not face the second gate electrode pattern, and formed in the substrate, and a second junction region arranged at a side wall of the second gate electrode pattern, which does not face the first gate electrode pattern, and formed in the substrate.

According to another aspect of the present disclosure, there is provided a non-volatile memory device including a substrate having formed thereon a step having an upper portion, a slope portion, and a lower portion, a first gate electrode pattern having a stacked structure in which an electric charge tunneling layer pattern, an electric charge trapping layer pattern, an electric charge shielding layer pattern, and a storage gate electrode pattern are conformably stacked on the step of the substrate, a gate insulating layer pattern extending from a side of the first gate electrode pattern formed on the upper portion of the step to the substrate, a second gate electrode pattern formed on the gate insulating layer pattern, a first junction region arranged at a side wall of the first gate electrode pattern, which does not face the second gate electrode pattern, and formed in the substrate, and a second junction region arranged at a side wall of the second gate electrode pattern, which does not face the first gate electrode pattern, and formed in the substrate.

According to still another aspect of the present disclosure, there is provided a method of manufacturing a non-volatile memory device, the method including providing a substrate, forming a trench in the substrate, forming a first gate electrode pattern having a stacked structure in which an electric charge tunneling layer pattern, an electric charge trapping layer pattern, an electric charge shielding layer pattern, and a storage gate electrode pattern are conformably stacked on the trench and a region of the substrate adjacent to the trench, forming a gate insulating layer pattern extending from a side of the first gate electrode pattern to the substrate and a second gate electrode pattern on the gate insulating layer pattern, and forming a first junction region arranged at a side wall of the first gate electrode pattern, which does not face the second gate electrode pattern, in the substrate and a second junction region arranged at a side wall of the second gate electrode pattern, which does not face the first gate electrode pattern, in the substrate.

According to yet another aspect of the present disclosure, there is provided a method of manufacturing a non-volatile memory device, the method including providing a substrate, forming a step having an upper portion, a slope portion, and a lower portion on the substrate, forming a first gate electrode pattern having a stacked structure in which an electric charge tunneling layer pattern, an electric charge trapping layer pattern, an electric charge shielding layer pattern, and a storage gate electrode pattern are conformably stacked on the step of the substrate, forming a gate insulating layer pattern extending from a side of the first gate electrode pattern formed on the upper portion of the step to the substrate and a second gate electrode pattern on the gate insulating layer pattern, and forming in the substrate a first junction region arranged at a side wall of the first gate electrode pattern, which does not face the second gate electrode pattern, and a second junction region arranged at a side wall of the second gate electrode pattern, which does not face the first gate electrode pattern.

### BRIEF DESCRIPTION OF THE DRAWINGS

The above and other features and advantages of the present disclosure will become more apparent by describing in detail preferred embodiments thereof with reference to the attached drawings in which:

FIG. 1 is a cross-sectional view of a non-volatile memory device according to an embodiment of the present disclosure;

FIGS. 2A through 2E are cross-sectional views for explaining a method of manufacturing the non-volatile memory device of FIG. 1 according to an embodiment of the present disclosure;

FIG. 3 is a cross-sectional view of a non-volatile memory device according to another embodiment of the present disclosure; and

FIGS. 4A through 4D are cross-sectional views for explaining a method of manufacturing the non-volatile memory device of FIG. 3 according to an embodiment of the present disclosure.

### DETAILED DESCRIPTION OF PREFERRED EMBODIMENTS

The advantages and features of the present invention and methods of using the same may be understood more readily by referring to the following detailed description of preferred embodiments and accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art. Thus, the present invention will only be limited by the appended claims. Like reference numerals may refer to like elements throughout the specification.

In the drawings, the thickness of layers and regions may be exaggerated for clarity. It will also be understood that when a layer is referred to as being “on” another layer or substrate, it can be directly on the other layer or substrate, or intervening layers may also be present. Further, while the following description is made on the assumption that a non-volatile memory device is of an NMOS type, it will be understood by those skilled in the art that the invention is also implemented by a PMOS type non-volatile memory device.

A non-volatile memory device according to the present disclosure is a floating trap type memory device having an oxide-nitride-oxide (ONO) trap structure and includes a trapping structure in which an electric charge tunneling layer, an electric charge trapping layer, and an electric charge shielding layer are sequentially stacked. Additionally, the non-volatile memory device includes a storage gate electrode and a control gate electrode. The non-volatile memory device is constructed such that an electric charge can be trapped using a vertical electric field formed by applying a voltage to the storage gate electrode and a horizontal electric field formed by applying a voltage to a source region and a drain region.

In particular, to trap an electric charge using the horizontal electric field, the electric charge trapping layer should be located on a path along which electric charges, e.g., electrons, move. To this end, a trench having a predetermined shape is formed in the substrate or the substrate is formed stepwise, and a trapping structure is formed on the trench or the stepwise substrate.

In such a structure, an electric charge, e.g., an electron moving horizontally with respect to a channel region of the substrate, may pass through the electric charge tunneling layer of the trapping structure without altering its direction and be trapped in the electric charge trapping layer. Since an electric charge, e.g., an electron in the channel region, is trapped in the electric charge trapping layer by the horizontal and vertical electric fields, an electric charge trapping operation, e.g., a program operation, can be performed with a smaller amount of current than in a conventional structure.

Thus, in the present disclosure, a control gate, further included to control the amount of current, is formed in a region between a source region and a drain region, except for a region where the trapping structure is formed.

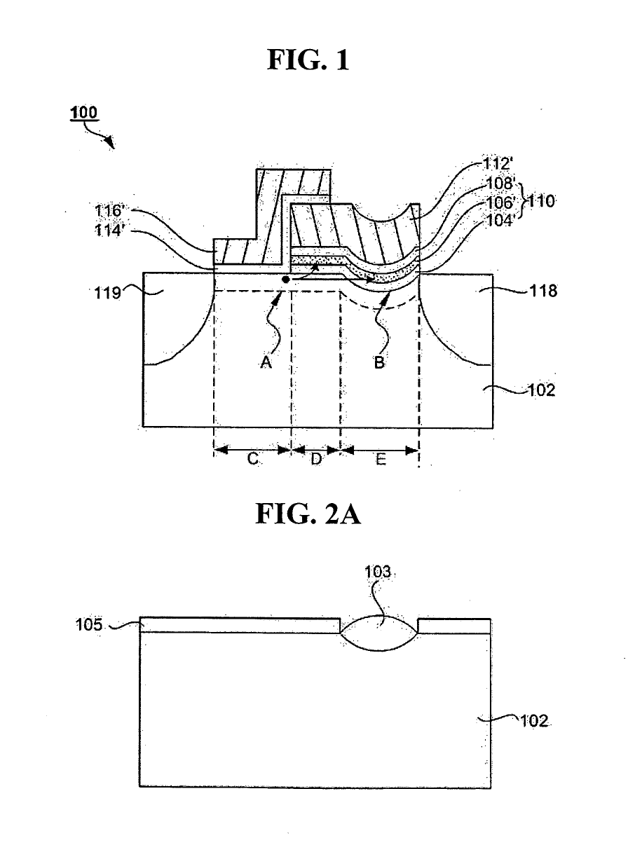

Hereinafter, the configuration and operations of a non-volatile memory device according the present disclosure will be described. FIG. 1 is a cross-sectional view of a non-volatile memory device according to an embodiment of the present disclosure.

Referring to FIG. 1, a non-volatile memory device 100 includes a substrate 102, an electric charge trapping structure pattern 110, a storage gate electrode pattern 112′, a gate insulating layer pattern 114′, and a control gate electrode pattern 116′.

The substrate 102 is formed of a semiconductor chemical element such as silicon (Si). A source region 118 and a drain region 119 are formed in the substrate 102. A trench B is formed in a portion of a region between the source region 118 and the drain region 119. A channel region A on the substrate 102 is indicated by a dotted line.

In the present embodiment, the trench B has a concave shape, but it may have other shapes as long as an electric charge trapping layer formed on the trench B is located on a path along which an electron moves horizontally without altering its direction.

The electric charge trapping structure pattern 110 is used to trap an electric charge passing through the channel region A of the substrate 102. To this end, the electric charge structure pattern 110 includes an electric charge tunneling layer pattern 104′, an electric charge trapping layer pattern 106′, and an electric charge shielding layer pattern 108′, which are sequentially stacked, and is formed on the trench B. The electric charge is tunneled through the electric charge tunneling layer pattern 104′. The electric charge is trapped in the electric charge trapping layer pattern 106′. The electric charge shielding layer pattern 108′ prevents the trapped electric charge from being tunneled to a storage gate electrode pattern 12a′. The electric charge trapping structure pattern 110 is extended to a predetermined length on the channel region A towards the drain region 119. In such a structure, the electric charge trapping structure pattern 110, in particular, the electric charge trapping layer pattern 106′, is located on a path along which an electric charge, e.g., an electron, moves horizontally through the channel region A. To this end, the depth of the trench B and the thickness of the electric charge tunneling layer pattern 104′ should be considered first when designing the non-volatile memory device 100.

The storage gate electrode pattern 112′ is formed of a conductive material on the electric charge trapping structure pattern 110. The storage gate electrode pattern 112′ is used to form the channel region A in the substrate 102 using a vertical electric field formed by applying a voltage to the storage gate electrode pattern 112′ and to allow an electric charge, e.g., an electron or a hole, existing in the channel region A to tunnel through the electric charge tunneling layer 104′ and to be trapped in the electric charge trapping layer pattern 106′.

The gate insulating layer pattern 114′ extends from a side wall adjacent to the drain region 119 to the drain region 119. It is preferable that the gate insulating layer pattern 114′ do not overlap with the drain region 119.

The control gate electrode pattern 116′ is formed of a conductive material like the material of the storage gate electrode pattern 112′ on the gate insulating layer pattern 114′. Here, the control gate electrode pattern 116′ does not need to be formed on the storage gate electrode pattern 112′. In order to control the amount of current caused by movement of electric charges in a reverse region formed in the channel region A, the control gate electrode pattern 116′ should be formed on a predetermined region C of the channel region A, unlike in FIG. 1 in which the control gate electrode pattern 116′ is also formed on the storage gate electrode pattern 112′.

Hereinafter, program, erase, and read operations of the non-volatile memory device 100 according to an embodiment of the present disclosure will be described.

First, the program operation will be described. Referring to FIG. 1, to program the non-volatile memory device 100, a positive bias voltage is applied to the storage gate electrode pattern 112′, a positive bias voltage is applied to the source region 118, and a positive bias voltage is applied to the drain region 119. A voltage lower than that applied to the storage gate electrode pattern 112′ is applied to the control gate electrode pattern 116′. For example, a voltage of about 3.0-5.0V is applied to the storage gate electrode pattern 112′, a voltage of about 3.5-5.5V is applied to the source region 118, and a voltage of about 1.0V or less or a ground voltage is applied to the drain region 119. A voltage of 2.0-4.0V is applied to the control gate electrode pattern 116′.

The channel region A is formed between the source region 118 and the drain region 119 by the voltages applied to the control gate electrode pattern 116′ and the storage gate electrode pattern 112′. Hot electrons are emitted from the drain region 119 toward the source region 118 along the channel region A. The generated hot electrons pass horizontally through the region C tunnel and pass through the electric charge tunneling layer pattern 104′, and are then trapped in the electric charge trapping layer pattern 106′ by a vertical electric field generated by the storage gate electrode pattern 112′ in a region D. Electrons that are not trapped in the region D move substantially horizontally in a region E, tunnel through the electric charge tunneling layer pattern 104′, and are then trapped in the electric charge trapping layer pattern 106′. Thus, a threshold voltage of a cell increases due to the program operation.

As such, during the program operation, electrons are trapped in the electric charge trapping layer pattern 106′ in the regions D and E, thereby allowing for a more efficient program operation than in a conventional non-volatile memory device structure. In particular, electrons trapped in the electric charge trapping layer pattern 106′ in the region E by the horizontal electric field can tunnel through the electric charge tunneling layer pattern 104′ with an energy smaller than that of electrons trapped in the electric charge trapping layer pattern 106′ in the region D by the vertical electric field. Accordingly a small amount of current flows in the channel region A unlike in a conventional non-volatile memory device structure. Thus, power consumption required for the program operation of the non-volatile memory device 100 can be reduced.

Next, the erase operation will be described. Referring to FIG. 1, for the erase operation, a negative bias voltage is applied to the storage gate electrode 116′, a positive bias voltage is applied to the source region 118, and a zero bias voltage is applied to the drain region 119. A negative bias voltage that is lower than that the voltage applied to the storage gate electrode pattern 116′ is applied to the control gate electrode pattern 116′. For example, during the erase operation, a voltage of about 4.5 -6.5V is applied to the source region 118, a zero voltage or a ground voltage is applied to the drain region 119, and a negative voltage of −4.5-−6.5V is applied to the storage gate electrode pattern 112′. A negative voltage of −4-−6V is applied to the control gate electrode pattern 116′.

The channel region A is formed between the source region 118 and the drain region 119 by the voltage applied to the storage gate electrode pattern 112′. Hot holes are emitted from the drain region 119 toward the source region 118 along the channel region A. The generated hot holes pass horizontally through the region C of the channel region A, tunnel through the electric charge tunneling layer pattern 104′, and are then trapped in the electric charge trapping layer pattern 106′ by a vertical electric field generated by the storage gate electrode pattern 112′ in the region D. Thus, the hot holes trapped in the electric charge trapping layer pattern 106′ are combined with the electrons that were trapped in the electric charge trapping layer pattern 106′ during the program operation, and disappear. Hot holes that are not trapped in the region D move substantially horizontally in the region E, tunnel through the electric charge tunneling layer pattern 104′ formed in the trench B, and are then trapped in the electric charge trapping layer pattern 106′. Thus, a threshold voltage of a cell is also reduced by the erase operation.

Alternatively, an erase operation may be performed in the following manner. That is, a negative bias voltage is applied to the storage gate electrode 112′ and a positive bias voltage is applied to the substrate 102, thereby leading electrons accumulated in the electric charge trapping layer pattern 106′ to the substrate 102. For example, a voltage of −12-−16V is applied to the storage gate electrode 112′ and a voltage of 4-7V is applied to the substrate 102.

Next, the read operation will be described. For the read operation, a voltage of 2.5-3.5V is applied to the storage gate electrode pattern 112′, a zero voltage or a ground voltage is applied to the source region 118, and a voltage of about 1V or less is applied to the drain region 119. Alternatively, a voltage of 1V or less may be applied to the source region 118 and a zero voltage or a ground voltage may be applied to the drain region 119. Here, when electrons are accumulated in the electric charge trapping layer pattern 106′, a current does not flow between the drain region 119 and the source region 118 because a channel is not induced between the drain region 119 and the source region 118. In this way, by detecting a current flowing between the drain region 119 and the source region 118, it is possible to determine whether electrons are accumulated in the electric charge trapping layer pattern 106′, that is, whether stored data is read.

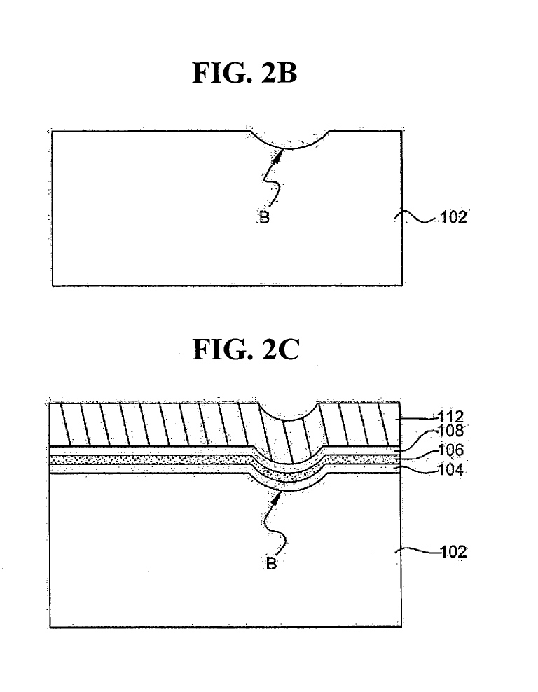

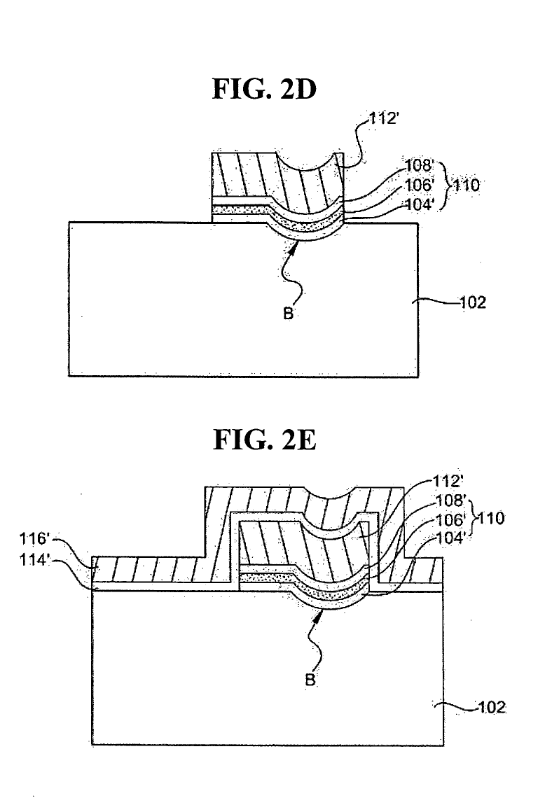

Hereinafter, a method of manufacturing the non-volatile memory device 100 according to an embodiment of the present disclosure will be described with reference to FIGS. 2A through 2E. FIGS. 2A through 2E are cross-sectional views for explaining a method of manufacturing the non-volatile memory device 100 of FIG. 1.

First, as shown in FIG. 2A, a semiconductor substrate 102 is provided and a nitride layer 105 is deposited on the semiconductor substrate 102. Next, a partial region of the nitride layer 105 is patterned using a photo process or a dry etching process until the top surface of the semiconductor substrate 102 is exposed. Then, an oxide layer 103 is formed by thermal oxidation using a Local-Oxidation of Silicon (LOCOS) process. Here, the oxide layer 103 is generally of a bird's beak type.

For reference, a concave type trench (B in FIG. 1) is to be formed in a region in which the oxide layer 103 is formed and an electric charge trapping layer pattern (106′ in FIG. 1) is to be formed on the concave type trench. As mentioned above, according to an embodiment of the present disclosure, since an electric charge, e.g., an electron, is trapped in an electric charge trapping layer pattern by a horizontal electric field, it is preferable that the electric charge trapping layer pattern be formed on an extension of a path along which an electron moves horizontally in a channel region (reverse region) in a substrate by the horizontal electric field. Thus, it is preferable that the oxide layer 103 be formed to a thickness according to such a structure. This is because the thickness of the oxide layer 103 determines the depth of the concave trench (B in FIG. 1) to be formed by removing the oxide layer 103 and an electric charge trapping layer pattern is to be formed on the concave trench.

As shown in FIG. 2B, the nitride layer 105 and the oxide layer 103 are removed by a wet etching method using ultra-low alpha lead (LAL), which is a mixture of ammonium fluoride (NH4F) and hydrogen fluoride, or H3PO4 as an etchant. After removal of the nitride layer 105 and the oxide layer 103, the concave trench B is formed on the semiconductor substrate 102.

Next, as shown in FIG. 2C, an electric charge tunneling layer 104, an electric charge trapping layer 106, an electric charge shielding layer 108, and a storage gate electrode layer 112 are sequentially, conformably formed using a chemical vapor deposition (CVD) method. Here, the electric charge tunneling layer 104 and the electric charge shielding layer 108 may be formed of an oxide material and the electric charge trapping layer 106 may be formed of a nitride material. The storage gate electrode layer 112 may be formed using polysilicon.

Next, as shown in FIG. 2D, a trapping structure pattern 110 including the electric charge tunneling layer pattern 104′, the electric charge trapping layer pattern 106′, the electric charge shielding layer pattern 108′, and the storage gate electrode pattern 112′ is formed by patterning the electric charge tunneling layer 104, and the electric charge trapping layer 106, the electric charge shielding layer 108, and the storage gate electrode layer 112 are formed using a photo process and a dry etching process until portions of the top surface of the semiconductor substrate 102 are exposed. Here, a polycide process or a salicide process using W, Co, or Ti may be additionally performed on the storage gate electrode pattern 112′.

Next, as shown in FIG. 2E, a gate insulating layer 114 and a control gate electrode layer 116 are sequentially, conformably deposited. Here, the gate insulating layer 114 may be formed using an oxide material and the control gate electrode layer 116 may be formed using an oxide material. The gate insulating layer 114 is not limited to a single oxide layer, but may have a stacked structure of a nitride layer and an oxide layer.

Finally, as shown in FIG. 1, the gate insulating layer pattern 114′ and the control gate electrode pattern 116′ are formed by patterning the gate insulating layer 114 and the control gate electrode layer 116 using a photo process and a dry etching process until portions of the top surface of the semiconductor substrate 102 are exposed. Here, a polycide process or a salicidation process using W, Co, or Ti may be additionally performed on the control gate electrode pattern 114′. Next, two junction regions, e.g., the source region 118 and the drain region 119, are formed using an ion implantation method.

After the storage gate electrode pattern 112′ and the control gate electrode pattern 116′ are formed, a polycide process or a salicidation process using WSix, CoSix, or TiSi may be performed.

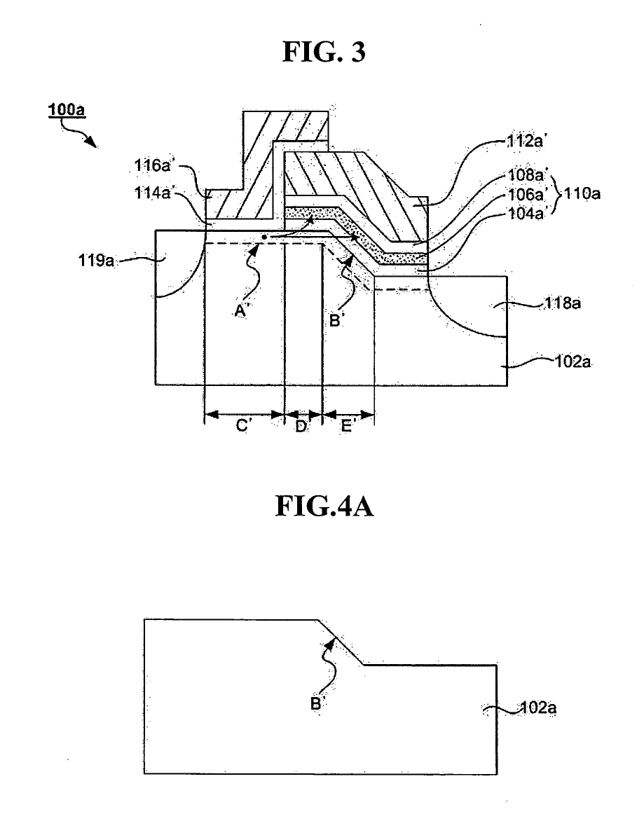

FIG. 3 is a cross-sectional view of a non-volatile memory device according to another embodiment of the present disclosure.

Referring to FIG. 3, a non-volatile memory device 100a includes a substrate 102a, an electric charge trapping structure pattern 110a, a storage gate electrode pattern 116a′, an insulating layer pattern 114a′, and a control gate electrode pattern 116a′.

The substrate 102a is formed of a semiconductor chemical element. A source region 118a and a drain region 119a are formed in the substrate 102a. A step B′ is formed between the source region 118a and the drain region 119a. The step B′ may be divided into an upper portion, a slope portion, and a lower portion according to its height and slope. A region indicated by a dotted line in the substrate 102a is a channel region A′.

The electric charge trapping structure pattern 110a is a structure for trapping an electric charge passing through the channel region A′ in the substrate 102a. To this end, the electric charge trapping structure pattern 110a has a stacked structure in which an electric charge tunneling layer pattern 104a′, an electric charge trapping layer pattern 106a′, and an electric charge shielding layer pattern 108a′ are sequentially stacked and is conformably formed on the step B′. Thus, the electric charge trapping structure pattern 110a is formed on the upper portion, the slope portion, and the lower portion of the step B′. In such a structure, the electric charge trapping structure 110a, in particular, the electric charge trapping layer 106a′, is located on a path along which an electric charge, e.g., an electron moving horizontally across the channel region A′. To this end, the height of the step B′ formed on the region E′ should be considered first when designing the non-volatile memory device 100a.

The storage gate electrode pattern 112a′ is formed of a conductive material on the electric charge trapping structure pattern 110a. The storage gate electrode pattern 112a′ is used to form the channel region A′ in the substrate 102a using a vertical electric field formed by an applied voltage and to allow an electric charge, e.g., an electron or a hole existing in the channel region A′, to tunnel through the electric charge tunneling layer 104a′ and to be trapped in the electric charge trapping layer pattern 106a′.

The gate insulating layer pattern 114a′ extends from a side wall of the storage gate electrode pattern 112a′ formed on the upper portion of the step B′ on the substrate 102.

The control gate electrode pattern 116a′ is formed of a conductive material on the gate insulating layer pattern 114a′ like the storage gate electrode pattern 112a′. Here, the control gate electrode pattern 116a′ does not need to be formed on the storage gate electrode pattern 112a′. In order to control the amount of current caused by movement of electric charges in a reverse region formed in the channel region A′, however, the control gate electrode pattern 116′ should be formed on a predetermined region C′ of the channel region A′.

The control gate electrode pattern 116a′ does not need to be formed on the storage gate electrode pattern 112a′, but should be formed on a predetermined region C′ of the channel region A′ to control the amount of current caused by movement of electric charges in a reverse region formed in the channel region A′.

Since program, read, and erase operations of the non-volatile memory device 100a are performed in the same manner as those of the non-volatile memory device 100, a detailed description thereof will be omitted and only a program operation will be described below.

To program the non-volatile memory device 100a, a positive bias voltage is applied to the storage gate electrode pattern 112a′, a positive bias voltage is applied to the source region 118a, and a positive or zero bias voltage is applied to the drain region 119a. A voltage that is lower than the voltage applied to the storage gate electrode pattern 112a′ is applied to the control gate electrode pattern 116a′. For example, a positive voltage of about 3.0-5.0V is applied to the storage gate electrode pattern 112a′, a voltage of about 3.5-5.5V is applied to the source region 118a, and a voltage of about 1.0V or less or a ground voltage is applied to the drain region 19a. A voltage of 2.0-4.0V is applied to the control gate electrode pattern 116a′.

A channel region is formed between the source region 118a and the drain region 119a by the voltage applied to the storage gate electrode pattern 112a′. Hot electrons are emitted from the drain region 119a toward the source region 118a along the channel region. The hot electrons pass horizontally through the region C′ of the channel region, tunnel through the electric charge tunneling layer pattern 104a′, and are then trapped in the electric charge trapping layer pattern 106a′ by a vertical electric field generated by the storage gate electrode pattern 12a′ in the region D′. Electrons that are not trapped in the region D′ move substantially horizontally in the region E′, tunnel through the electric charge tunneling layer pattern 104a′ formed in a trench B′, and are then trapped in the electric charge trapping layer pattern 106a′. Thus, a threshold voltage of a cell is increased by the program operation.

As such, in the program operation, electrons are trapped in the electric charge trapping layer pattern 106a′ in two regions, i.e., the regions D′ and E′, thereby allowing for a more efficient program operation than in a conventional non-volatile memory device structure. In particular, electrons trapped in the electric charge trapping layer pattern 106a′ in the region E′ by a horizontal electric field can tunnel through the electric charge tunneling layer pattern 104a′ with an energy smaller than that of electrons trapped in the electric charge trapping layer pattern 106a′ in the region D′ by the vertical electric field. Accordingly, a small current flows in the channel region A′ unlike in a conventional non-volatile memory device structure. Thus, power consumption required for the program operation of the non-volatile memory device 100a can be reduced.

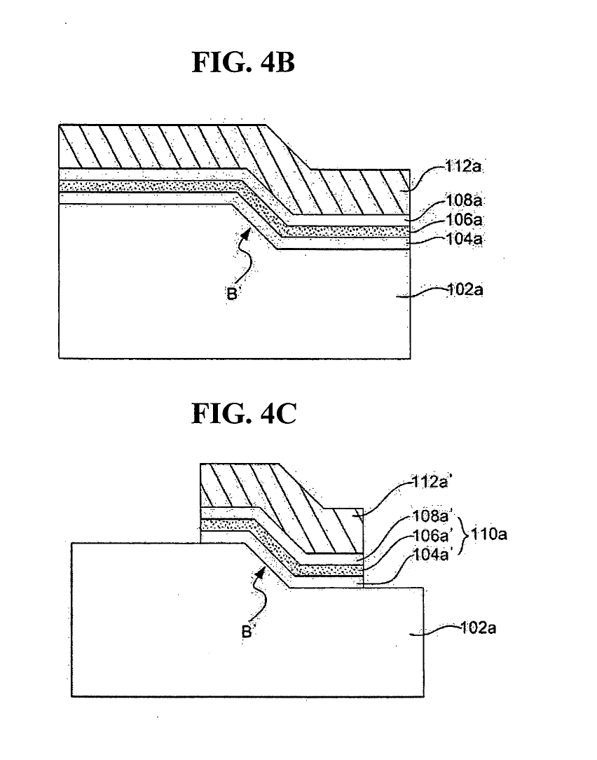

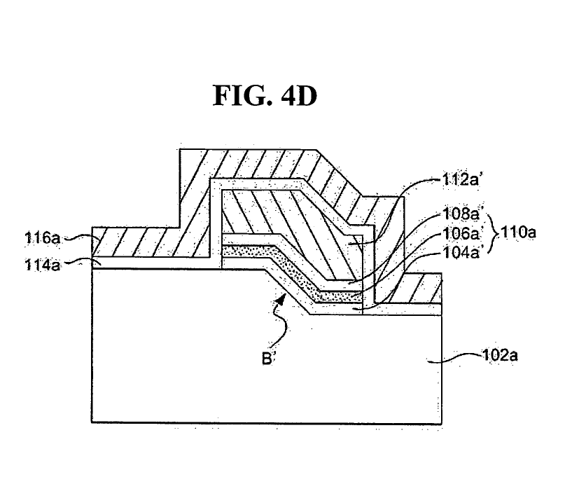

Hereinafter, a method of manufacturing the non-volatile memory device 100a according to an embodiment of the present disclosure will be described with reference to FIGS. 3 and FIGS. 4A through 4D. Since the method of manufacturing the non-volatile memory device 100a is similar to the method of manufacturing the non-volatile memory device 100, only a brief description thereof will be given. FIGS. 4A through 4D are cross-sectional views for explaining the method of manufacturing the non-volatile memory device 100a of FIG. 3.

First, as shown in FIG. 4A, the substrate 102a is provided. The substrate 102a is then patterned to form the step B′ having a slope using a photo process and an etching process.

Next, as shown in FIG. 4B, the electric charge tunneling layer 104a, the electric charge trapping layer 106a, the electric charge shielding layer 108a, and the storage gate electrode layer 112a are sequentially, conformably deposited. Here, the electric charge tunneling layer 104a and the electric charge shielding layer 108a may be formed using an oxide material, the electric charge trapping layer 106a may be formed using a nitride material, and the storage gate electrode layer 112a may be formed using polysilicon.

Next, as shown in FIG. 4C, the electric charge tunneling layer 104a, the electric charge trapping layer 106a, the electric charge shielding layer 108a, and the storage gate electrode layer 112a are patterned using a photo process and an etching process until portions of the top surface of the substrate 102a are exposed. Then, the electric charge trapping structure pattern 110a has a stacked structure in which the electric charge tunneling layer pattern 104a′, the electric charge trapping layer pattern 106a′, and the electric charge shielding layer pattern 108a′ are sequentially formed, and the storage gate electrode pattern 112a′ is formed on the electric charge trapping structure pattern 110a.

Next, as shown in FIG. 4D, the gate insulating layer 114a and the control gate electrode layer 116a are conformably deposited. Here, the gate insulating layer 114a may be formed of an oxide material and the control gate electrode layer 116a may be formed of polysilicon.

As shown in FIG. 3, the gate insulating layer pattern 114a′ and the control gate electrode pattern 116a′ are formed by patterning the gate insulating layer 114a and the control gate electrode layer 116a. The source region 118a and the drain region 119a are then formed.

In concluding the detailed description of preferred embodiments, those skilled in the art will appreciate that many variations and modifications can be made to the exemplary embodiments described above without departing from the principles of the present invention. Therefore, the disclosed preferred embodiments of the invention are used in a generic and descriptive sense only and not for purposes of limitation.

What is claimed is:

1. A non-volatile memory device comprising:
a substrate having at least one sloped portion formed therein;
a first gate electrode pattern having a stacked structure in which an electric charge tunneling layer pattern, an electric charge trapping layer pattern, an electric charge shielding layer pattern, and a storage gate electrode pattern are conformably stacked on the at least one sloped portion;
a gate insulating layer pattern extending from a side of the first gate electrode pattern to the substrate;
a second gate electrode pattern formed on the gate insulating layer pattern;
a first junction region arranged at a side wall of the first gate electrode pattern, which does not face the second gate electrode pattern, and formed in the substrate; and
a second junction region arranged at a side wall of the second gate electrode pattern, which does not face the first gate electrode pattern, and formed in the substrate.

2. The non-volatile memory device of claim 1 wherein the at least one sloped portion comprises a trench.

3. The non-volatile memory device of claim 1 wherein the at least one sloped portion comprises a step having a substantially horizontal upper portion, a substantially sloped middle portion, and a lower portion.

4. The non-volatile memory device of claim 3 wherein the first gate electrode pattern stacked structure is conformably stacked on at least the upper portion and the middle portion.

5. The non-volatile memory device of claim 1 wherein the electric charge tunneling layer pattern is formed of an oxide, the electric charge trapping layer pattern is formed of a nitride, and the electric charge shielding layer pattern is formed of an oxide.

6. The non-volatile memory device of claim 1 wherein the storage gate electrode pattern and the control gate electrode pattern are formed of polysilicon.

7. The non-volatile memory device of claim 1 wherein the gate insulating layer pattern is a single layer of an oxide layer or a nitride layer, or a combination layer having a stack of these layers.

8. The non-volatile memory device of claim 1 wherein the first gate electrode pattern or the second gate electrode pattern has a polycide structure.

9. The non-volatile memory device of claim 1 wherein the first gate electrode pattern or the second gate electrode pattern has a salicide structure.

10. A method of manufacturing a non-volatile memory device, the method comprising:
providing a substrate;
forming at least one sloped portion in the substrate;
forming a first gate electrode pattern having a stacked structure in which an electric charge tunneling layer pattern, an electric charge trapping layer pattern, an electric charge shielding layer pattern, and a storage gate electrode pattern are conformably stacked on the at least one sloped portion;
forming a gate insulating layer pattern extending from a side of the first gate electrode pattern to the substrate and a second gate electrode pattern on the gate insulating layer pattern; and
forming a first junction region arranged at a side wall of the first gate electrode pattern, which does not face the second gate electrode pattern, in the substrate and a second junction region arranged at a side wall of the second gate electrode pattern, which does not face the first gate electrode pattern, in the substrate.

11. The method of claim 10 wherein the at least one sloped portion comprises a trench.

12. The method of claim 10 wherein the at least one sloped portion comprises a step having a substantially horizontal upper portion, a substantially sloped middle portion, and a lower portion.

13. The method of claim 12 wherein the first gate electrode pattern stacked structure is conformably stacked on at least the upper portion and the middle portion.

14. The method of claim 10 wherein the electric charge tunneling layer pattern is formed of an oxide, the electric charge trapping layer pattern is formed of a nitride, and the electric charge shielding layer pattern is formed of an oxide.

15. The method of claim 10 wherein the storage gate electrode pattern and the control gate electrode pattern are formed of polysilicon.

16. The method of claim 10 wherein the gate insulating layer pattern is a single layer of an oxide layer or a nitride layer, or a combination layer having a stack of these layers.

17. The method of claim 10 further comprising performing a polycide process on the first gate electrode pattern after forming the first gate electrode pattern.

18. The method of claim 10 further comprising performing a polycide process on the second gate electrode pattern after forming the second gate electrode pattern.

19. The method of claim 10 further comprising performing a salicidation process on the first gate electrode pattern forming the first gate electrode pattern.

20. The method of claim 10 further comprising performing a salicidation process on the second gate electrode pattern after forming the second gate electrode pattern.
